(19) United States
(12) Patent Application Publication
(10) Pub. No.: US 2016/0055976 A1
(43) Pub. Date: Feb. 25, 2016

(54) PACKAGE SUBSTRATES INCLUDING EMBEDDED CAPACITORS

(71) Applicant: QUALCOMM Incorporated, San Diego, CA (US)

(72) Inventors: Young Kyu Song, San Diego, CA (US); Kyu-Pyung Hwang, San Diego, CA (US)

(21) Appl. No.: 14/468,212

(22) Filed: Aug. 25, 2014

(51) Int. Cl. H01G 4/30; H01L 21/768; H01G 4/12; H01G 4/232; H01G 4/248; H01L 23/522; H01G 4/012

(52) U.S. Cl. CPC H01G 4/30; H01L 23/5222; H01L 23/5226; H01L 21/7687; H01L 21/76802; H01G 4/012; H01G 4/232; H01G 4/248; H01G 4/12

(57) ABSTRACT

Integrated devices include a substrate, and a capacitor embedded within the substrate. The capacitor is configured to include a first electrode disposed on a first surface, a second electrode disposed on an opposing second surface, and a plurality of capacitor plates extending transverse between the first electrode and the second electrode. Each capacitor plate is electrically coupled to one of the first electrode or the second electrode. A plurality of vias are positioned to extend through the substrate to one of the first electrode or the second electrode. Other aspects, embodiments, and features are also included.

### TECHNICAL FIELD

The technology discussed below relates generally to package substrates including embedded capacitors.

### BACKGROUND

Embedded capacitors can be integrated into a package substrate for various purposes. For example, an embedded capacitor may be employed as a decoupling capacitor in, for instance, a power supply line. Generally, if voltage in a power supply line varies significantly due to an impedance between the power supply line and a ground, the voltage variation may cause the operation of a driven circuit to be unstable, cause inter-circuit interference via the power supply circuit, and generate an oscillation. To avoid these problems, a decoupling capacitor is usually connected between the power supply line and the ground. The decoupling capacitor reduces the impedance between the power supply line and the ground, and suppresses variations of the power supply voltage and the inter-circuit interference.

Recently, in communication equipment, such as cell-phones, for example, and information processing equipment, such as personal computers, for example, there is a trend toward a higher signal rate and a higher clock frequency of ICs used therein to process a greater amount of information. Therefore, noise including greater amounts of higher harmonic components is more likely to occur, and an IC power supply circuit requires stronger decoupling.

To increase the decoupling effect, a decoupling capacitor with a superior impedance-frequency characteristic may be used. One example of such a decoupling capacitor is a multilayer ceramic capacitor. The multilayer ceramic capacitor has a smaller ESL (equivalent series inductance) and has a higher noise absorption effect over a wider frequency band than an electrolytic capacitor.

Another role of the decoupling capacitor is to supply charges to an IC. Usually, the decoupling capacitor is disposed near the IC. When a voltage variation occurs in the power supply line, charges are quickly supplied to the IC from the decoupling capacitor so as to prevent a delay in the supply of the charges to the IC.

During a charge or a discharge to or from a capacitor, a counter electromotive force dV expressed by a formula of dV=L·di/dt is generated. If dV has a large value, supply of the charge to the IC is delayed. With an increasing demand for a higher clock frequency of the IC, a current variation di/dt per unit time tends to increase. Thus, the inductance L must be reduced in order to reduce dV. Therefore, there is a need for capacitors with further reduced ELS (equivalent series inductance).

### BRIEF SUMMARY OF SOME EXAMPLES

The following summarizes some aspects of the present disclosure to provide a basic understanding of the discussed technology. This summary is not an extensive overview of all contemplated features of the disclosure, and is intended neither to identify key or critical elements of all aspects of the disclosure nor to delineate the scope of any or all aspects of the disclosure. Its sole purpose is to present some concepts of one or more aspects of the disclosure in summary form as a prelude to the more detailed description that is presented later.

Various features, apparatus, and methods described herein provide a package substrate that includes embedded capacitors. According to at least one aspect, substrates are provided. In one or more embodiments, the substrate may include a dielectric layer with a capacitor embedded therein. The capacitor may include a first electrode disposed on a first surface and a second electrode disposed on an opposing second surface. A plurality of capacitor plates may be positioned between the first electrode and the second electrode to extending transverse to the first and second electrodes, with each capacitor plate electrically coupled to one of the first electrode or the second electrode. A plurality of vias may extend through the dielectric, with at least one via electrically coupled to the first electrode of the capacitor, and at least one via electrically coupled to the second electrode of the capacitor.

Additional aspects of the present disclosure include methods of fabricating a substrate. One or more implementations of such methods may include providing a first dielectric layer. A cavity may be formed within the first dielectric layer. A capacitor may be provided within the cavity of the first dielectric layer, where the capacitor includes a first electrode disposed on a first surface and a second electrode disposed on an opposing second surface such that the first electrode and the second electrode are positioned within the cavity to be at least substantially parallel with a top and bottom surface of the dielectric layer. The capacitor further includes a plurality of capacitor plates positioned between the first electrode and the second electrode and extending transverse thereto, where each capacitor plate is electrically coupled to one of the first electrode or the second electrode. A second dielectric layer may be provided to at least substantially enclose the capacitor therein. A plurality of vias may be formed through the first dielectric and the second dielectric, with at least one via electrically coupled to the first electrode of the capacitor, and with at least one via electrically coupled to the second electrode of the capacitor.

Still further aspects of the present disclosure include electronic devices. In one or more embodiments, such an electronic device may include an integrated device with a substrate and a capacitor embedded within the substrate. The capacitor may include a first electrode disposed on a first surface, and a second electrode disposed on an opposing second surface. The capacitor further includes a plurality of capacitor plates positioned between the first electrode and the second electrode and extending transverse thereto, where each capacitor plate is electrically coupled to one of the first electrode or the second electrode. A plurality of vias may extend through the substrate, where at least one via is electrically coupled to the first electrode of the capacitor, and where at least one via is electrically coupled to the second electrode of the capacitor.

Other aspects, features, and embodiments associated with the present disclosure will become apparent to those of ordinary skill in the art upon reviewing the following description in conjunction with the accompanying figures.

### DRAWINGS

FIG. 1 is a cross-sectional side view of a package substrate including a substrate and a capacitor embedded within the substrate according to at least one embodiment.

FIG. 2 is an isometric view of an embedded capacitor according to at least one embodiment.

FIG. 3 is a cross-sectional side view of the capacitor in FIG. 2 according to at least one embodiment.

FIG. 4 is a cross-sectional side view of the capacitor in FIG. 2 according to an embodiment including a resistive layer disposed on first and second electrodes.

FIG. 5 is a top view of a package substrate showing vias over a first electrode of an embedded capacitor according to at least one embodiment.

FIG. 6 is a cross-sectional side view of a package substrate illustrating a current flow path though the capacitor and vias according to at least one embodiment.

FIG. 7 is a conceptual circuit diagram illustrating one example of a power distribution network (PDN) in which package substrates of the present disclosure may be employed.

FIG. 8 is another conceptual circuit diagram illustrating another example of a power distribution network (PDN) in which package substrates of the present disclosure may be employed.

FIG. 9 is a cross-sectional side view of a package substrate that includes a capacitor.

FIG. 10 is a cross-sectional side view of another package substrate that includes a capacitor.

FIG. 11 (including FIGS. 11A-11L) includes cross-sectional side views illustrating a sequence for providing a package substrate that includes an embedded capacitor.

FIG. 12 is a flow diagram illustrating at least one example of a method for providing an integrated device including a capacitor embedded within a substrate.

FIG. 13 illustrates a flow diagram of a modified semi-additive processing (mSAP) patterning process for manufacturing a substrate.

FIG. 14 illustrates a sequence of a mSAP patterning process on a layer of a substrate.

FIG. 15 illustrates a flow diagram of a semi-additive processing (SAP) patterning process for manufacturing a substrate.

FIG. 16 illustrates a sequence of a SAP patterning process on a layer of a substrate.

FIG. 17 illustrates a flow diagram of a conceptual plating process.

FIG. 18 is a conceptual diagram illustrating various electronic devices that may be integrated with any of the integrated devices of the present disclosure.

### DETAILED DESCRIPTION

The description set forth below in connection with the appended drawings is intended as a description of various configurations and is not intended to represent the only configurations in which the concepts and features described herein may be practiced. The following description includes specific details for the purpose of providing a thorough understanding of various concepts. However, it will be apparent to those skilled in the art that these concepts may be practiced without these specific details.

The illustrations presented herein are, in some instances, not actual views of any particular package substrate or embedded capacitor, but are merely idealized representations which are employed to describe the present disclosure. Additionally, elements common between figures may retain the same numerical designation.

### Overview

Integrated devices (e.g., semiconductor devices, die packages) of the present disclosure include a substrate with an embedded capacitor. The capacitor includes electrodes horizontally disposed over top and bottom surfaces, with vertically positioned capacitor plates extending between the two electrodes and each capacitor plate coupled to one of the two electrodes. A plurality of vias extend through a portion of the substrate and are electrically coupled to one of the electrodes of the capacitor.

### Exemplary Package Substrates

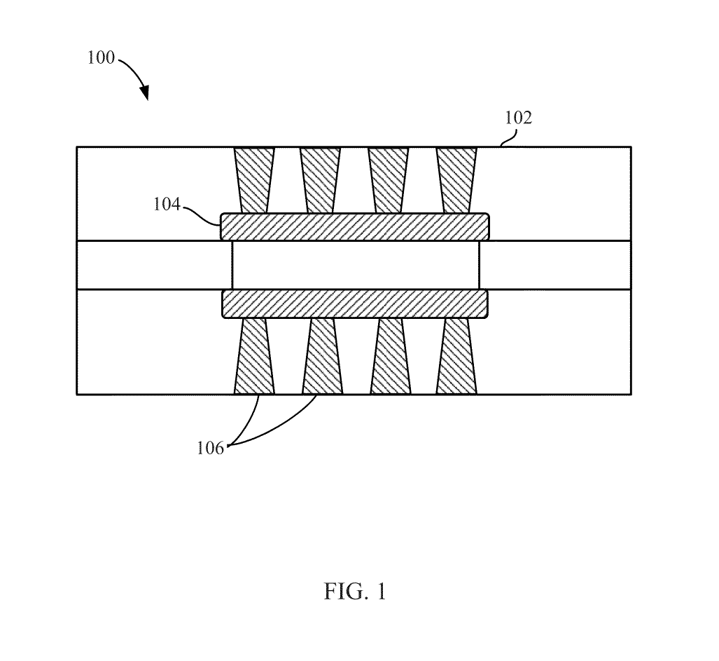

FIG. 1 illustrates a cross-sectional side view of a package substrate 100 that includes a substrate 102 and a capacitor 104 embedded within the substrate 102. A plurality of vias 106 extend through a portion of the substrate 102 to the capacitor 104, as described in more detail below.

The substrate 102 may be formed of any of a plurality of suitable materials, depending on the particular implementation. By way of example and not limitation, the substrate 100 may be formed of silicon, glass, ceramic, and/or dielectric materials. Additionally, the substrate may be configured to receive one or more other discrete devices electrically coupled thereto.

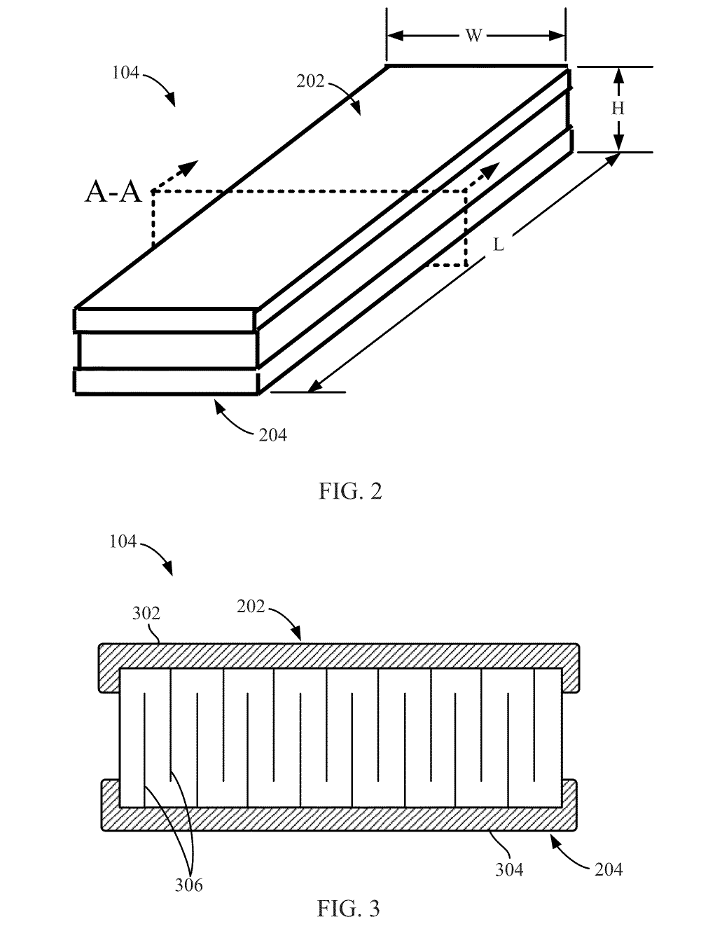

The capacitor 104 is disposed within a portion of the substrate 102. Referring to FIG. 2, an isometric view of a capacitor 104 is illustrated according to at least one embodiment. The capacitor 104 may generally be configured with a longitudinal length ‘L’, a width ‘W’, and a height ‘H’, where the length ‘L’ is substantially larger than the width ‘W’ and the height ‘H’. As a result, the capacitor 104 includes a first surface (top surface) 202 and a second surface (bottom surface) 204 each with a surface area defined by the length ‘L’ and width ‘W’. By way of example and not limitation, at least one embodiment may be configured with a length ‘L’ that is about twice the size of the width ‘W’. For instance, the capacitor 104 may be formed with a length ‘L’ of about 1 millimeter (1 mm), a width ‘W’ of about 0.5 millimeter (0.5 mm), and a height ‘H’ of about 0.1-0.2 millimeter (0.1 mm-0.2 mm).

Turning to FIG. 3, a cross-sectional side view of the capacitor 104 is shown as taken across section plane A-A shown by broken lines in FIG. 2. The capacitor 104 includes a first electrode 302 disposed over the first surface 202, and a second electrode 304 positioned over the opposing second surface 204. In at least some embodiments, the first and second electrodes 302, 304 can be formed of copper, although other embodiments may employ different electrically conductive materials. The capacitor 104 further includes a plurality of capacitor plates 306 positioned at least substantially vertically within the capacitor 104. That is, the capacitor plates 306 extend transverse to the first and second electrodes 302, 304. The capacitor plates 306 may be separated from one another by a dielectric material, such as a ceramic material. In such examples, the capacitor 104 can be formed as a multi-layer ceramic capacitor (MLCC). Some of the capacitor plates 306 are electrically coupled to the first electrode 302, and the other capacitor plates 306 are electrically coupled to the second electrode 304, in a layered fashion as shown in FIG. 3.

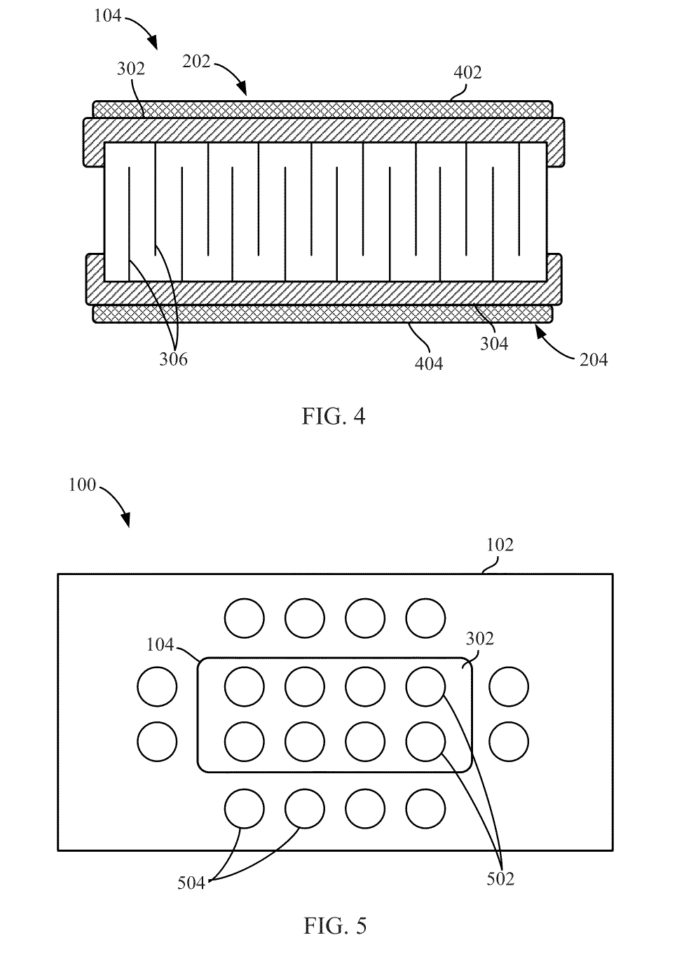

In some embodiments, an optional resistive layer may be disposed over at least a portion of the first and second electrodes 302, 304. For example, FIG. 4 shows an embodiment of the capacitor from FIG. 3 with a resistive layer disposed on the first and second electrodes 302, 304 according to one example. More specifically, a first resistive layer 402 is disposed over at least a portion of the first electrode 302 and a second resistive layer 404 is disposed over at least a portion of the second electrode 304. The resistive layers 402. 404 may be a material configured to provide a predetermined resistance. In at least one example, the resistive layers 402, 404 may be a conductive material layer having a predefined resistance. The resistive layers 402, 404 can facilitate control of equivalent series resistance (ESR), by controlling the resistance of the connection between the electrodes 302, 304 and the vias (e.g., vias 106 in FIG. 1).

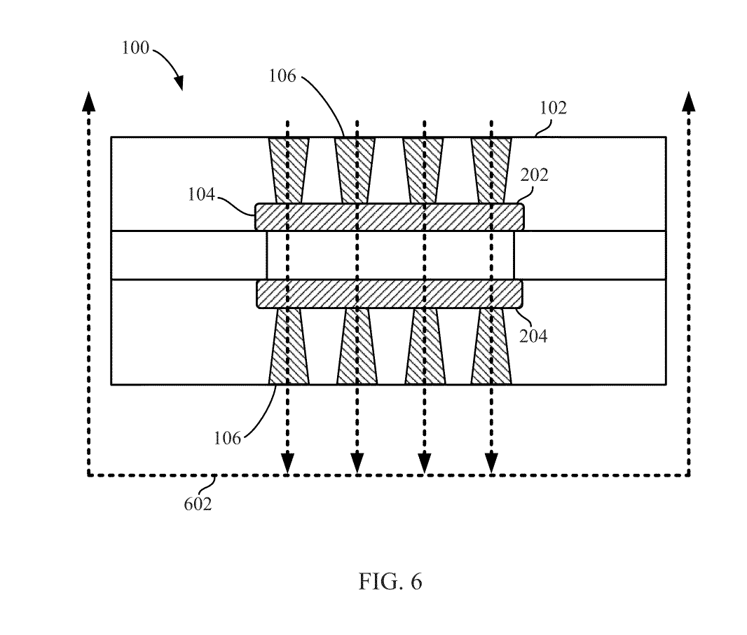

As set forth above, the first electrode 302 and second electrode 304 are respectively disposed on at least substantially all of the first surface 202 and second surface 204, which are relatively large surfaces. As a result, the first and second electrodes 302, 304 provide relatively large surfaces to which vias (e.g., vias 106 in FIG. 1) within the substrate may be electrically coupled. For example, FIG. 5 illustrates a top view of the package substrate 100 from FIG. 1 showing vias (e.g., vias 106 in FIG. 1) over the first electrode 302 according to at least one example. As illustrated, a plurality of vias 502 can be positioned to extend to the first electrode 302 of the capacitor 104. The plurality of vias 502 can be disposed in the substrate 102 over the entire surface of the first electrode 302. In this example, there are eight vias 502 that are electrically coupled with the first electrode 302. Although not shown, the second electrode 304 would have a similar surface area and would facilitate a similar number of via connections. In this embodiment, a plurality of vias 504 (shown positioned around the capacitor 104) can also be disposed within the substrate 102 extending from a top surface to a bottom surface. The vias 504 can be coupled by conductive traces to vias coupled to the second electrode 304.

In some implementations, the vias 502 may be configured to provide an electrical path for signals (e.g., power signals, data signals) to the capacitor in the substrate 100, and the vias 504 may be configured to provide an electrical path for ground from the capacitor in the substrate 100. In some implementations, the vias 504 may be configured to provide an electrical path for signals (e.g., power signals, data signals) to the capacitor in the substrate 100, and the vias 502 may be configured to provide an electrical path for ground from the capacitor in the substrate 100.

The significantly larger surface area of the first electrode 302 (and the second electrode 304 not shown in FIG. 5) facilitates a significantly larger than typical number of vias within the package substrate 100 to be coupled to the capacitor 104. By increasing the number of vias coupled to each electrode, the package substrates 100 of the present disclosure can provide a relatively lower equivalent series inductance (ESL) within circuitry coupled to the vias. For instance, the increased number of vias enables for connections with shorter conductive paths to the capacitor 104, which can result in lower equivalent series inductance (ESL).

Additionally, embodiments of the capacitor 104 in the present package substrate 100 include lower equivalent series inductance (ESL) within the capacitor 104 itself. That is, the AC current path through the capacitor 104 is configured in a manner that results in a reduction of equivalent series inductance (ESL). For instance, the relatively short height (height ‘H’ in FIG. 2) and the relatively wide surface (surfaces 202 and 204 in FIG. 2) facilitate a lower equivalent series inductance (ESL) in the capacitor 104. As shown in FIG. 6, the current flow path can generally follow the broken lines 602 through the capacitor 104. That is, the vias 106 electrically coupled to the top surface 202 can enable current flow down toward the capacitor 104. The current continues to flow through the capacitor 104 to the bottom surface 204, and through the vias 106 electrically coupled to the bottom surface 204.

### Exemplary Power Distribution Networks

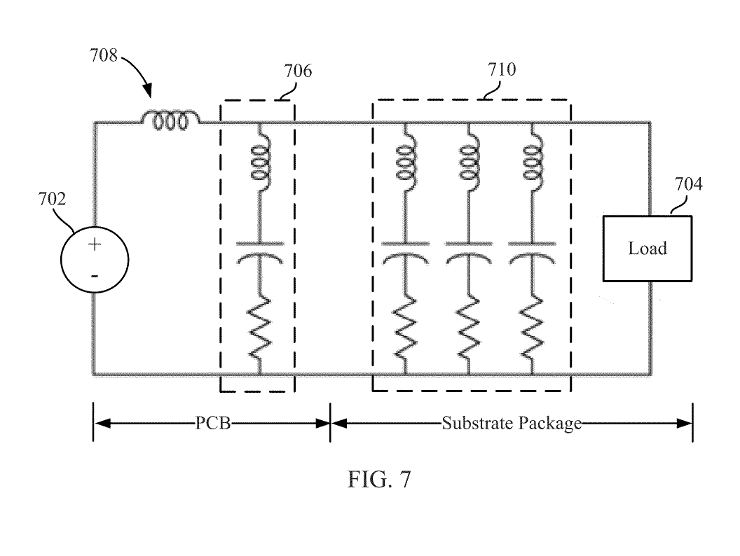

The reduction in ESL can be beneficial in various applications. For example, embodiments of the package substrate 100 described herein may find application in a power distribution network (PDN). FIG. 7 is a circuit diagram illustrating one example of a power distribution network (PDN) in which a package substrate 100 of the present disclosure may be employed. A typical PDN includes a printed circuit board (PCB) connecting a power management circuit (PMIC) 702 to a package substrate (e.g., package substrate 100) with one or more loads 704 coupled thereto (e.g., an integrated circuit (IC) die). Capacitances and inductance of the PCB are respectively modeled by elements 706 (board cap) and 708 (Lbrd). The PDN further includes a package substrate with at least one embedded decoupling capacitor 710. In this example, three embedded decoupling capacitors 710 are illustrated, although the actual number of embedded decoupling capacitors 710 in a given embodiment may vary according to the specific applications and according to one or more design factors. According to aspects of the present disclosure, one or more of the embedded decoupling capacitors 710 are configured according to one or more embodiments described herein, such as those described above with reference to FIGS. 1 through 6.

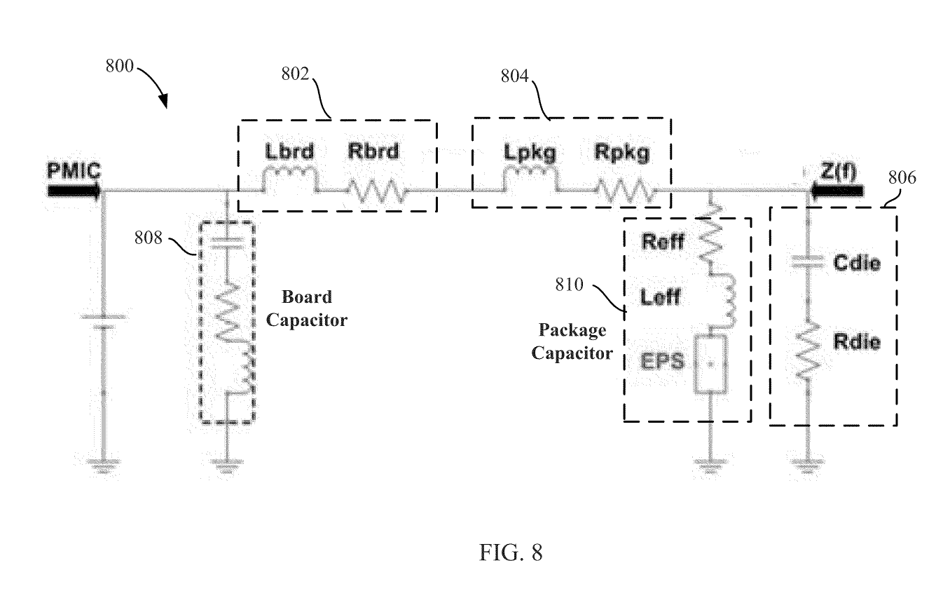

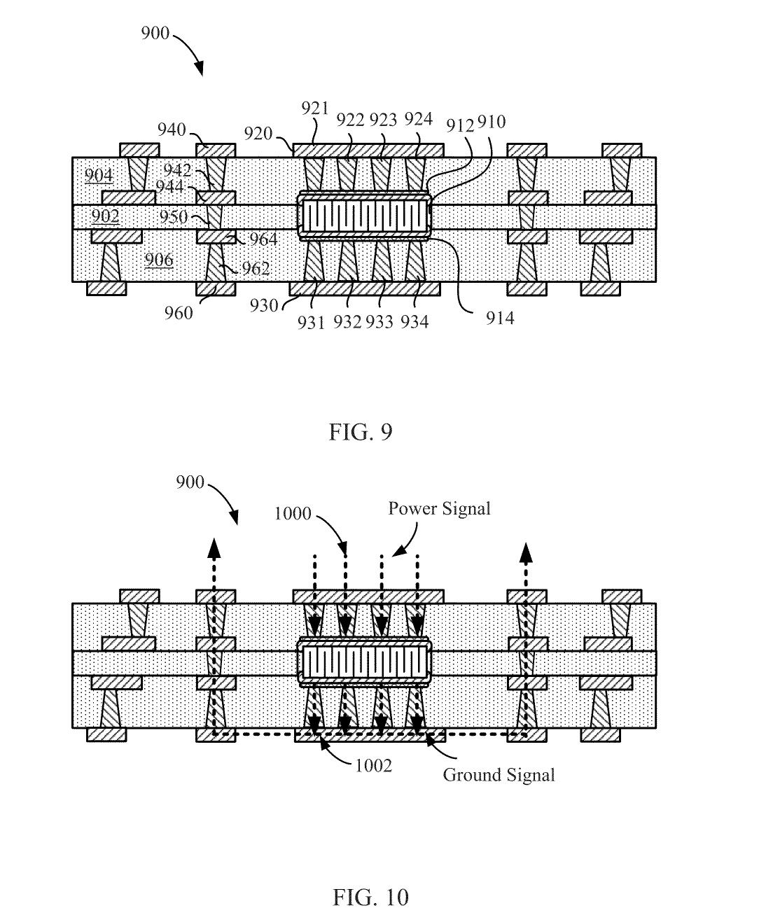

FIG. 8 illustrates another circuit diagram for a power distribution network (PDN). Specifically, FIG. 8 illustrates a circuit diagram 800 of a power distribution network for an integrated device that includes a printed circuit board (PCB), a package substrate, a die, and a capacitor.

As shown in FIG. 8, the circuit diagram 800 includes a printed circuit board (PCB) circuit component 802 (e.g., printed circuit board), a package (e.g., package substrate) circuit component 804 (e.g., package substrate), a die circuit component 806 (e.g., die), a PCB capacitor circuit component 808, and a package capacitor circuit component 810 (e.g., embedded package capacitor (EPS)). The PCB circuit component 802 includes an inductance (L_{brd}), and a resistance (R_{brd}). The PCB circuit component 802 includes an inductance (L_{brd}), and a resistance (R_{brd}). The package circuit component 804 includes an inductance (L_{pkg}), and a resistance (R_{pkg}). The die circuit component 806 includes an inductance (L_{die}), and a resistance (R_{die}). The package capacitor circuit component 810 includes an effective inductance (L_{eff}), and a resistance (R_{eff}). The package capacitor circuit component 810 may be an embedded package capacitor, such as the capacitor 104 described in FIGS. 3 and/or 4. The PCB capacitor circuit component 808 is a capacitor that may be embedded in the PCB.

FIG. 8 illustrates that the (PCB) circuit component 802, the package circuit component 804, and the die circuit component 806 are electrically coupled together in series in the circuit diagram 800. The package capacitor circuit component 810 is electrically coupled in parallel to the die circuit component 806 in the circuit diagram 800.

### Exemplary Package Substrate Including an Embedded Capacitor

FIG. 9 illustrates an example of a package substrate 900 that includes an embedded capacitor 910. In some implementations, the embedded capacitor 910 may be the capacitor 104 described in FIGS. 3 and/or 4, described above.

FIG. 9 illustrates that the package substrate 900 includes a core layer 902, a first prepeg layer 904, and a second prepeg layer 906. In some implementations, the package substrate 900 may be coreless. That is the package substrate 900 may not include the core layer 902.

The capacitor 910 is embedded in the package substrate 900. Specifically, the capacitor 910 is located in at least the core layer 902 of the package substrate 900. A first resistive layer 912 is coupled to a first portion (e.g., top portion) of the capacitor 910, and a second resistive layer 914 is coupled to a second portion (e.g., bottom portion) of the capacitor 910.

The package substrate 900 includes a first interconnect 920 (e.g., pad) on a first surface (e.g., top surface) of the package substrate 900. The first prepeg layer 904 includes a first set of vias 921-924. The first set of vias 921-924 is coupled to the first interconnect 920 and the first resistive layer 912. In some implementations, the first set of vias 921-924 may be coupled to a first portion of the capacitor 910.

The package substrate 900 also includes a second interconnect 930 (e.g., pad) on a second surface (e.g., bottom surface) of the package substrate 900. The second prepeg layer 906 includes a second set of vias 931-934. The second set of vias 931-934 is coupled to the second interconnect 920 and the second resistive layer 914. In some implementations, the second set of vias 931-934 may be coupled to a second portion of the capacitor 910.

As shown in FIG. 9, the package substrate 900 also includes a first pad 940, a third via 942, a second pad 944, a fourth via 950, a third pad 960, a fifth via 962 and a fourth pad 964. The first pad 940 is coupled to the third via 942. The third via 942 is coupled to the second pad 944. The second pad 944 is coupled to the fourth via 950. The fourth via 950 is coupled to the fourth pad 964. The fourth pad 964 is coupled to the fifth via 962. The first via 962 is coupled to the third pad 960. In some implementations, the third pad 960 is coupled to the second interconnect 930 (either directly or indirectly). The third pad 960 may be coupled to the second interconnect 930 through one or more interconnects (e.g., traces, pads, vias). Different implementations may provide an electrical power signal through the capacitor 910 using different configurations.

FIG. 10 illustrates an example of a path that an electrical power signal may be provided through a capacitor 910. As shown in FIG. 10, a power signal 1000 is provided to the capacitor 910 through the first interconnect 920, the first set of vias 921-924, and the first resistive layer 912 (which is optional). Once the power signal 1000 is provided to the capacitor 910, a ground signal 1002 exits from the capacitor 910 through the second resistive layer 914 (which is also optional), the second set of vias 931-934, and the second interconnect 930.

Once the ground signal 1002 has reached the second interconnect 930, in some implementations, the ground signal traverses to the pad 960 (directly or indirectly through one or more interconnects), the via 962, the pad 964, the via 950, the pad 944, the via 942, and the pad 940. It should be noted that FIG. 10 is merely an example of a path that a signal may take in a package substrate. The path of the signal may vary in the package substrate in different implementations.

### Exemplary Sequence for Providing a Package Substrate Including an Embedded Capacitor

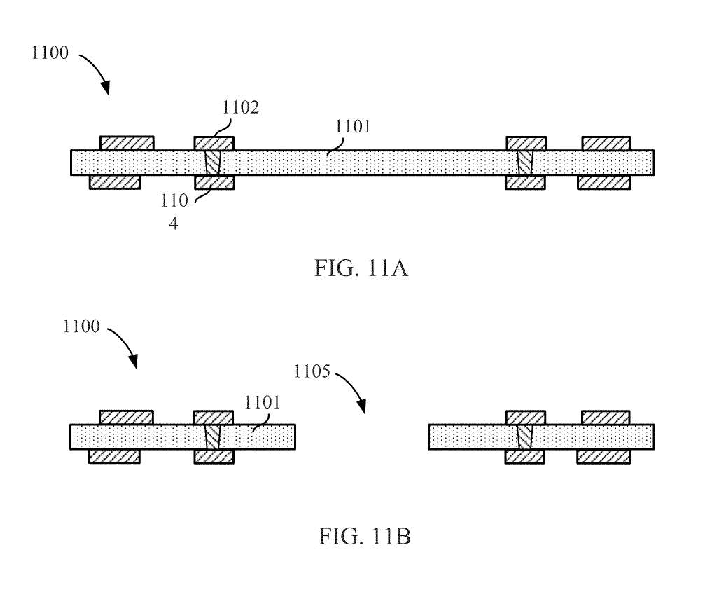

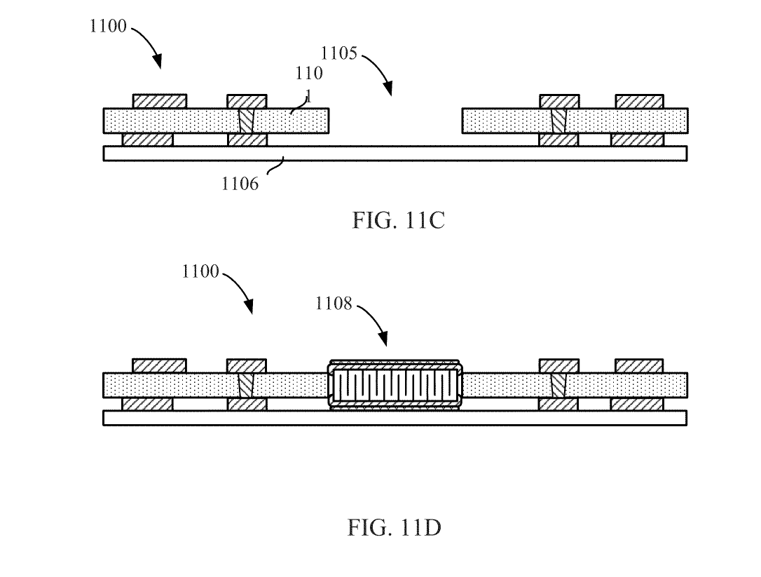

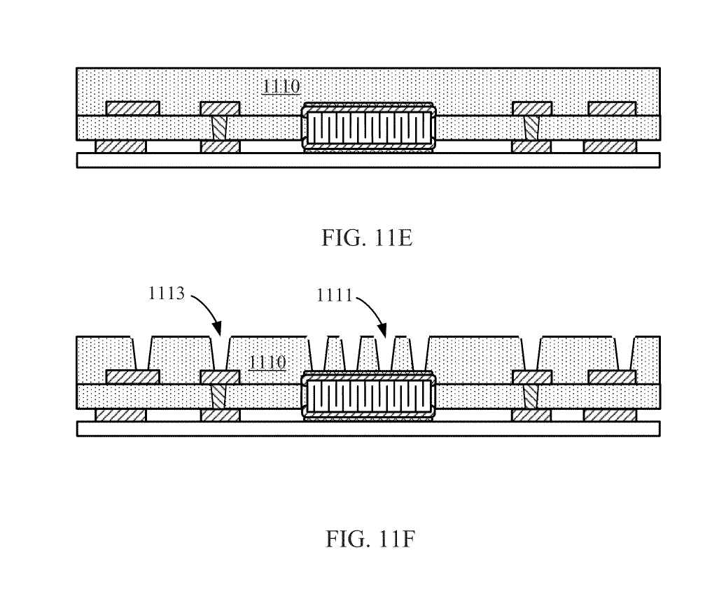

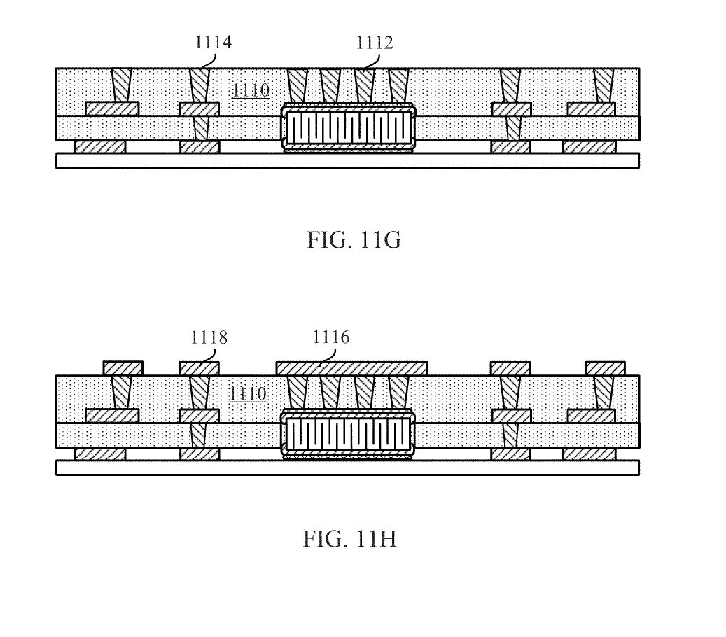

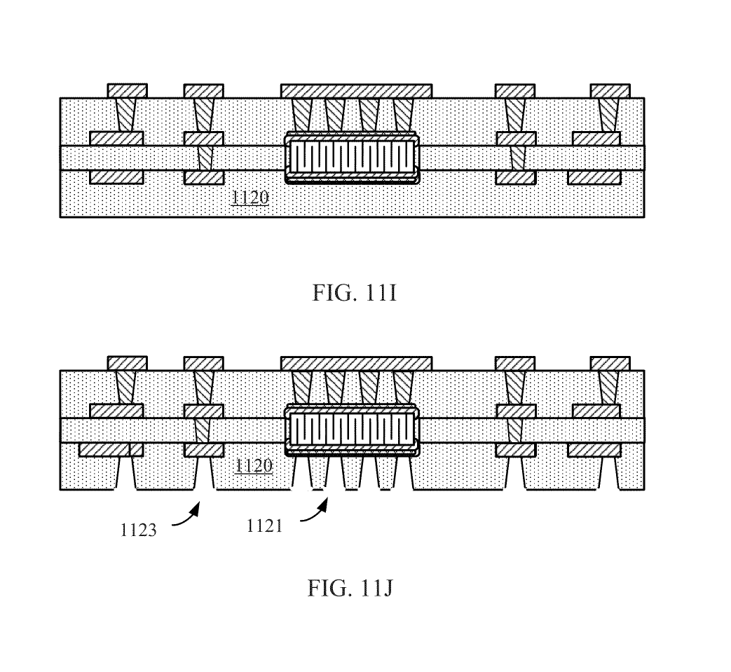

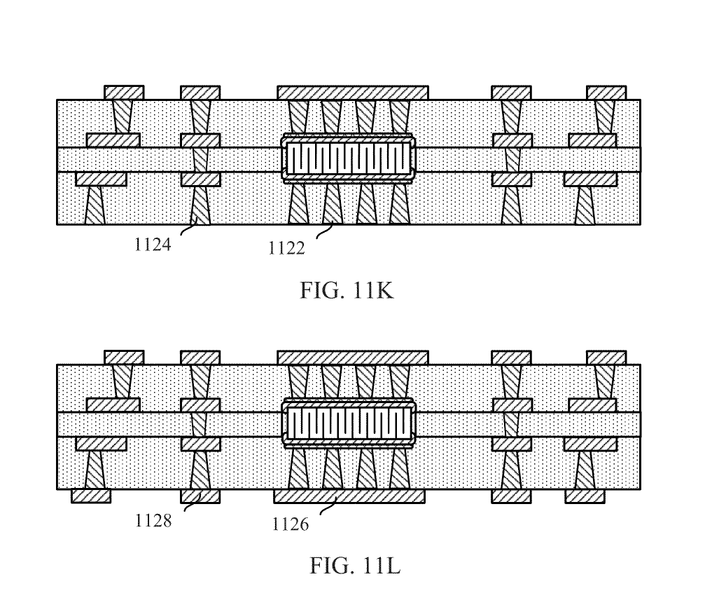

FIG. 11 (which includes FIGS. 11A-11L) illustrates a sequence for providing/manufacturing/fabricating a package substrate that includes an embedded capacitor. It is noted that for purpose of clarity and simplification, the processes described with references to FIGS. 11A-11L do not necessarily include all the steps and/or stages of manufacturing a package substrate. Moreover, in some instances, several steps and/or stages may have been combined into a single step and/or stage in order to simplify the description of the process. Further, the shapes of the patterns, pattern features, components, interconnects (e.g., trace, vias) in FIGS. 11A-11L are merely conceptual illustrations and are not intended to necessarily represent the actual size, shape and form of the patterns, pattern features and components. In some implementations, FIGS. 11A-11L may be used to provide and/or fabricate the package substrate 900 of FIG. 9.

FIG. 11A illustrates a substrate 1100 that includes a first dielectric layer 1101, and interconnects 1102 and 1104. In some implementations, the first dielectric layer 1101 is a core layer of the substrate 1100. The interconnect 1102 is on a first surface (e.g., top surface) of the first dielectric layer 1101, and the interconnect 1104 is on a second surface (e.g., bottom surface) of the first dielectric layer 1101. The interconnects 1102 and 1104 may be traces and/or pads.

FIG. 11B illustrates the substrate 1100 after a cavity 1105 is formed in the substrate 1100. As shown in FIG. 11B, the cavity 1105 completely traverses the substrate 1100. In some implementations, the cavity 1105 may partially traverse the substrate 1100. That is, a cavity 1105 may partially traverse the first dielectric layer 1101. Different implementations may use different processes for forming the cavity 1105 in the substrate 1100. In some implementations, the cavity 1105 is formed by using a laser to remove the at least some of the first dielectric layer 1101. In some instances, a photo-etching process is used to remove at least some of the first dielectric layer 1101.

FIG. 11C. illustrates the substrate 1100 after being positioned on a carrier 1106. Different implementations may use different carriers. The carrier 1106 may include one of at least a substrate and/or a wafer. The substrate 1100 may be coupled to the carrier 1106 using a bonding agent (e.g., glue).

FIG. 11D illustrates the substrate 1100 after a capacitor 1108 is positioned in the cavity 1105. Different implementations may use different capacitors, such as the capacitors described above in FIGS. 1, 2, 3, 4 for example. The capacitor 1108 may be coupled to the carrier 1106 and/or the first dielectric layer 1101 using a bonding agent (e.g., glue). The capacitor 1108 is positioned in the capacitor is positioned in the cavity 1105 such that a first side (e.g., top electrode side) of the capacitor 1108 is on the same as the first surface (e.g., top surface) of the substrate 1100, and a second side (e.g., bottom electrode side) of the capacitor 1106 is on the same side as the second surface (e.g., bottom surface) of the substrate 1100. It should be noted that the surface of the capacitor 1108 does not necessarily need to be perfectly aligned with the surfaces of the first dielectric layer 1101. However, in some implementations, at least one surface of the capacitor 1108 may be aligned with at least one surface of the first dielectric layer 1101 and/or at least one surface of the substrate 1100.

FIG. 11E illustrates a state after a second dielectric layer 1110 is provided (e.g., formed) on the first surface (e.g., top surface) of the substrate 1100. As shown in FIG. 11E, the second dielectric layer 1110 covers the interconnect 1102 and the capacitor 1108. In some implementations, the second dielectric layer 1110 is a prepeg layer.

FIG. 11F illustrates a state after at least one cavity (e.g., cavity 1111, cavity 1113) is formed in the second dielectric layer 1110. Some of the cavities may be formed over portions of the interconnect 1102 and the capacitor 1108. In some implementations, a laser is used to selectively remove portions of the second dielectric layer 1110. In some implementations, a photo-etching process may be used to selectively remove portions of the second dielectric layer 1110.

FIG. 11G illustrates a state after the cavities in the second dielectric layer 1110 is filled with a conductive material to define one or more vias (e.g., via 1112, via 1114) in the second dielectric layer 1110. As shown in FIG. 11G, the vias traverse the second dielectric layer 1110 and are coupled to the interconnect 1102 and the capacitor 1108. For example, the via 1112 is coupled to a first electrode (e.g., top electrode) of the capacitor 1108. In instances when the capacitor 1108 also includes a resistive layer (e.g., resistive layer 402), the via 1112 would be coupled to the resistive layer. The resistive layer may be provided (e.g., formed) on the capacitor 1108 before the capacitor 1108 is positioned in the substrate 1100, or the resistive layer may be formed on the capacitor 1108 (e.g., on the electrode of the capacitor) before vias are defined in the dielectric layers. The via 1114 is coupled to the interconnect 1102.

FIG. 11H illustrates a state after a first interconnect 1118 and a second interconnect 1116 are formed on the second dielectric layer 1110. The first interconnect 1118 may be a pad that is coupled to the via 1114 that is coupled to the interconnect 1102. The second interconnect 1116 may be a trace that is coupled to one or more vias (e.g., via 1112), which are coupled to the capacitor 1108.

FIG. 11I illustrates a state after the carrier 1106 is removed and a third dielectric layer 1120 is provided (e.g., formed) on the second surface (e.g., bottom surface) of the substrate 1100. In some implementations, the carrier 1106 may be removed by using an etching process. As shown in FIG. 11I, the third dielectric layer 1120 covers the interconnect 1104 and the capacitor 1108. In some implementations, the third dielectric layer 1120 is a prepeg layer.

FIG. 11J illustrates a state after at least one cavity (e.g., cavity 1121) is formed in the third dielectric layer 1120. Some of the cavities may be formed over portions of the interconnect 1104 and the capacitor 1108. In some implementations, a laser is used to selectively remove portions of the third dielectric layer 1120. In some implementations, a photo-etching process may be used to selectively remove portions of the third dielectric layer 1120.

FIG. 11K illustrates a state after the cavities in the third dielectric layer 1120 is filled with a conductive material to define one or more vias (e.g., via 1122, via 1124) in the third dielectric layer 1120. As shown in FIG. 11K, the vias traverse the third dielectric layer 1120 and are coupled to the interconnect 1104 and the capacitor 1108. For example, the via 1122 is coupled to a second electrode (e.g., bottom electrode) of the capacitor 1108. In instances when the capacitor 1108 also includes a resistive layer (e.g., resistive layer 402), the via 1122 would be coupled to the resistive layer. The resistive layer may be provided (e.g., formed) on the capacitor 1108 before the capacitor 1108 is positioned in the substrate 1100, or the resistive layer may be formed on the capacitor 1108 (e.g., on the electrode of the capacitor) before vias are defined in the dielectric layers. The via 1124 is coupled to the interconnect 1104.

FIG. 11L illustrates a state after a third interconnect 1128 and a fourth interconnect 1126 are formed on the third dielectric layer 1120. The third interconnect 1128 may be a pad that is coupled to the via 1124 that is coupled to the interconnect 1104. The fourth interconnect 1126 may be a trace that is coupled to one or more vias (e.g., via 1122), which are coupled to the capacitor 1108.

It should be noted that additional dielectric layers may be formed on either or both sides of the substrate. For example additional prepeg layers may be formed to the substrate. In some implementations, the substrate that is illustrated in FIG. 11L is a laminate substrate.

### Exemplary Method for Providing a Package Substrate

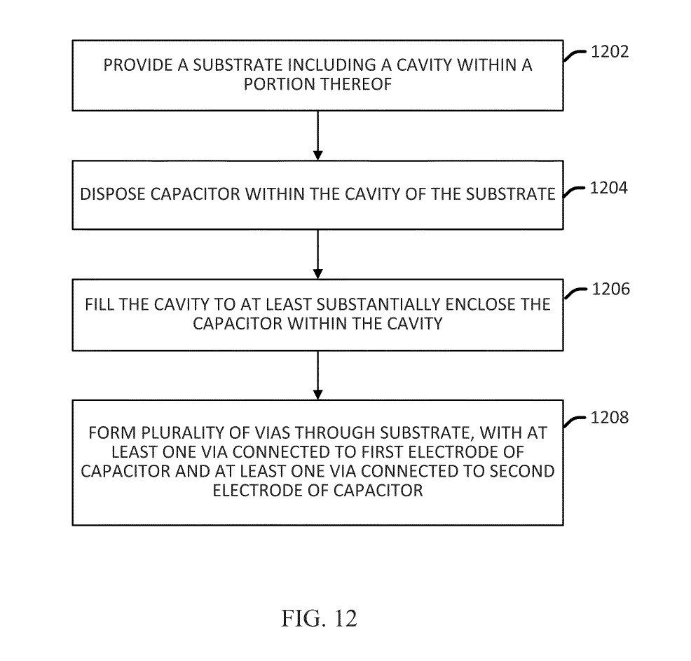

FIG. 12 illustrates at least one example of a method for providing, manufacturing, and/or fabricating an integrated device including a capacitor embedded within a substrate. It should be noted that for the purpose of clarity and simplification, the processes of FIG. 12 do not necessarily include all the steps and/or stages of manufacturing an integrated device. Moreover, in some instances, several steps and/or stages may have been combined into a single step and/or stage in order to simplify the description of the processes.

As shown in FIG. 12, a substrate may be provided at 1202. Providing a substrate may include fabricating (e.g., forming) a substrate or receiving a substrate from a supplier. Different implementations may use different materials for the substrate. In some implementations, the substrate may include one of at least silicon, glass, ceramic and/or dielectric. In some implementations, the substrate may include several layers (e.g., laminate substrate that includes core layer and several prepreg layers).

The provided substrate may include a cavity therein. In some implementations, the method may provide a cavity in the substrate. Providing the cavity in the substrate may include fabricating (e.g., forming, creating) the cavity in the substrate or receiving the substrate from a supplier with the cavity formed therein. In implementations where the cavity is formed in the substrate, different manufacturing processes may be used for providing the cavity. By way of example only, a cavity may be formed by conventional etching processes (e.g., laser, chemical, reactive ion), drilling, or otherwise forming the cavity.

At 1204, a capacitor may be disposed within the cavity of the substrate. The capacitor is positioned within the cavity with the first and second electrodes substantially parallel with a top and bottom surface of the substrate. The capacitor is configured similar to one or more of the embodiments described herein above with reference to FIGS. 1-4. In general, the capacitor includes a first electrode disposed on a top surface, a second electrode disposed on an opposing bottom surface, and a plurality of capacitor plates positioned substantially perpendicular to, and extending between, the first electrode and the second electrode.

In some examples, a resistive layer can be provided on the electrodes of the capacitor. For example, the resistive layer can be included on a capacitor received from a supplier, or the resistive layer may be formed on the first and second electrodes. In at least one implementation, the resistive layer can be screen printed on the first and second electrodes of the capacitor.

At 1206, the cavity can be filled to substantially enclose the capacitor within the cavity. Filling the cavity may include disposing a material into the cavity and/or positioning a material over the cavity. The material can be the same material for the substrate, or a different material. In some implementations, the cavity may be filled with one of at least silicon, glass, ceramic and/or dielectric. In some implementations, the cavity may filled with an insert that is glued or otherwise fixedly disposed within and/or over the cavity.

At 1208, a plurality of vias are formed through the substrate (including the material used to fill/cover the cavity). The vias can be formed according to conventional techniques for creating apertures in the substrate and filling those aperture with an electrically conductive material. At least one via is formed in electrical connection with the first electrode of the capacitor, and at least one via is formed in electrical connection with the second electrode of the capacitor.

### Exemplary Flow Diagram for Plating Process

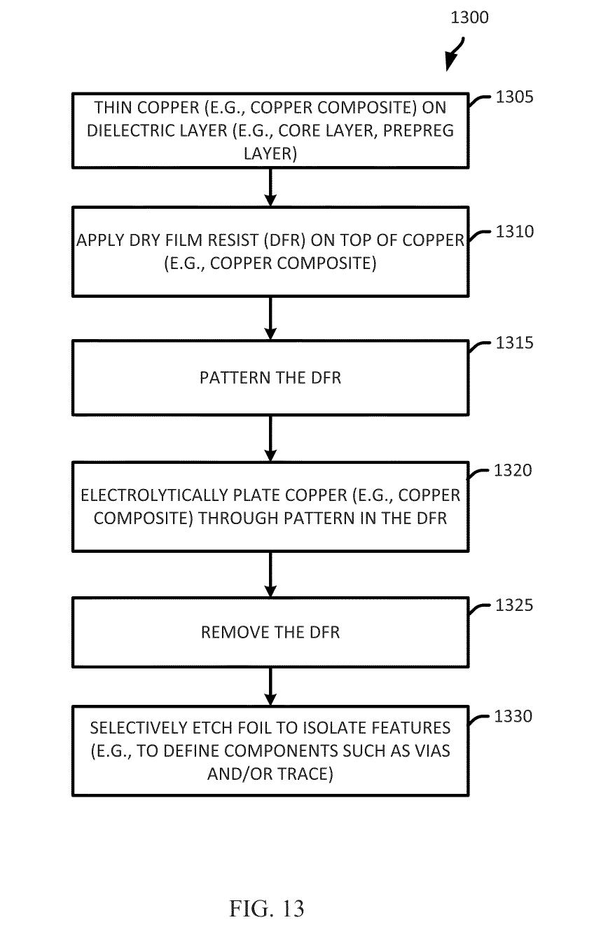

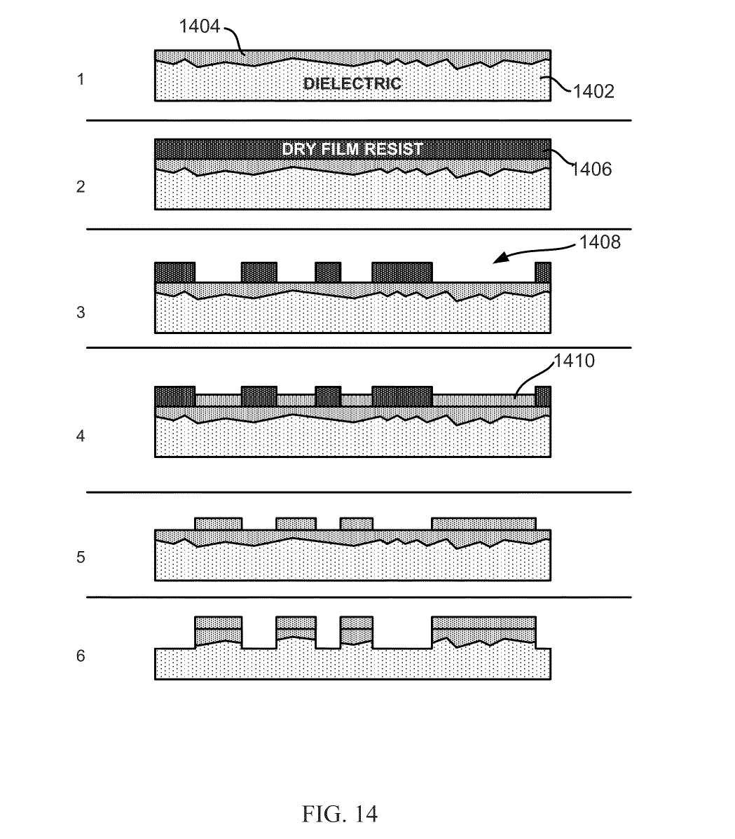

FIG. 13 illustrates a flow diagram for a modified semi-additive processing (mSAP) patterning process for manufacturing a substrate. FIG. 13 will be described with reference to FIG. 14 which illustrates a sequence of a layer (e.g., core layer, prepreg layer) of a substrate during the mSAP process of some implementations.

As shown in FIG. 13, the process 1300 may start by thinning (at 1305) a metal layer (e.g., copper composite material) on a dielectric layer. The dielectric layer may be a core layer or a prepreg layer of the substrate. In some implementations, the metal layer is thinned to a thickness of about 3-5 microns (μm). The thinning of the metal layer is illustrated in stage 1 of FIG. 14, which illustrates a dielectric layer 1402 that includes a thin copper layer 1404 (which may be a copper composite material). In some implementations, the metal layer may already be thin enough. For example, in some implementations, the core layer or dielectric layer may be provided with a thin copper foil. As such, some implementations may bypass/skip thinning the metal layer of the core layer/dielectric layer. In addition, in some implementations electroless copper seed layer plating may performed to cover the surface of any drilled vias in one or more dielectric layers.

Next, the process applies (at 1310) a dry film resist (DFR) and a pattern is created (at 1315) on the DFR. Stage 2 of FIG. 14 illustrates a DFR 1406 being applied on top of the thinned metal layer 1404, while stage 3 of FIG. 14 illustrates the patterning of the DFR 1406. As shown in stage 3, the patterning creates openings 1408 in the DFR 1406.

After patterning (at 1315) the DFR, the process then electrolytically plates (at 1320) a copper material (e.g., copper composite) through the pattern of the DFR. In some implementations, electrolytically plating comprises dipping the dielectric and the metal layer in a bath solution. Referring to FIG. 14, stage 4 illustrates copper materials (e.g., copper composite) 1410 being plated in the openings 1408 of the DFR 1406.

Referring back to FIG. 13, the process removes (at 1325) the DFR, selectively etches (at 1330) the copper foil material (e.g., copper composite) to isolate the features (e.g., create components such vias, composite conductive traces, and/or pads) and ends. Referring to FIG. 14, stage 13 illustrates the removal of the DFR 1406, while stage 6 illustrates the defined features after the etching process. The above process of FIG. 14 may be repeated for each core layer or prepreg layer (dielectric layer) of the substrate. Having described one plating process, another plating process will now be described.

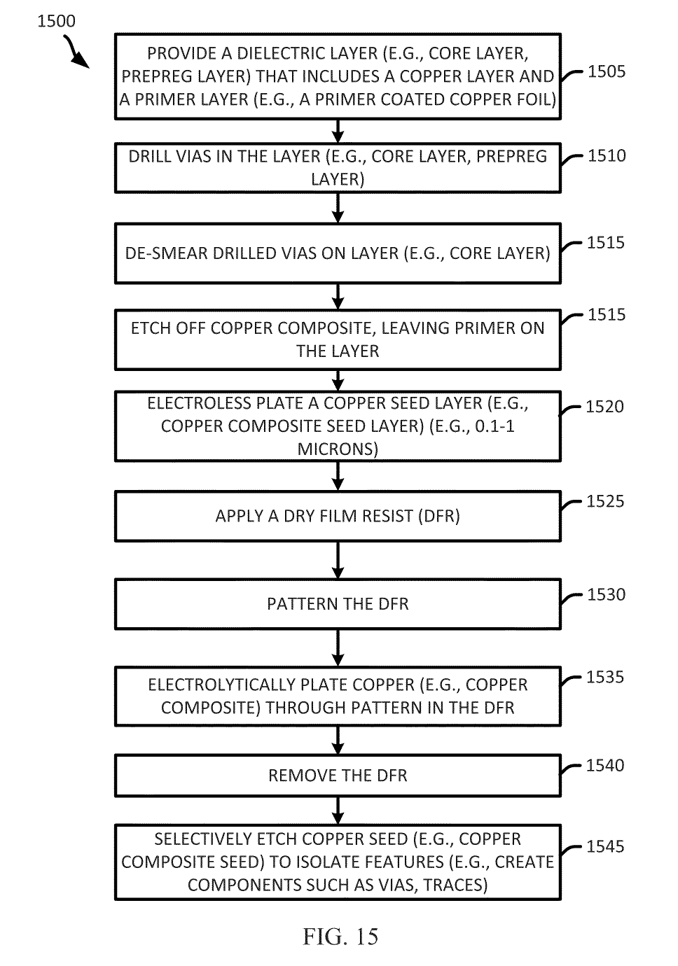

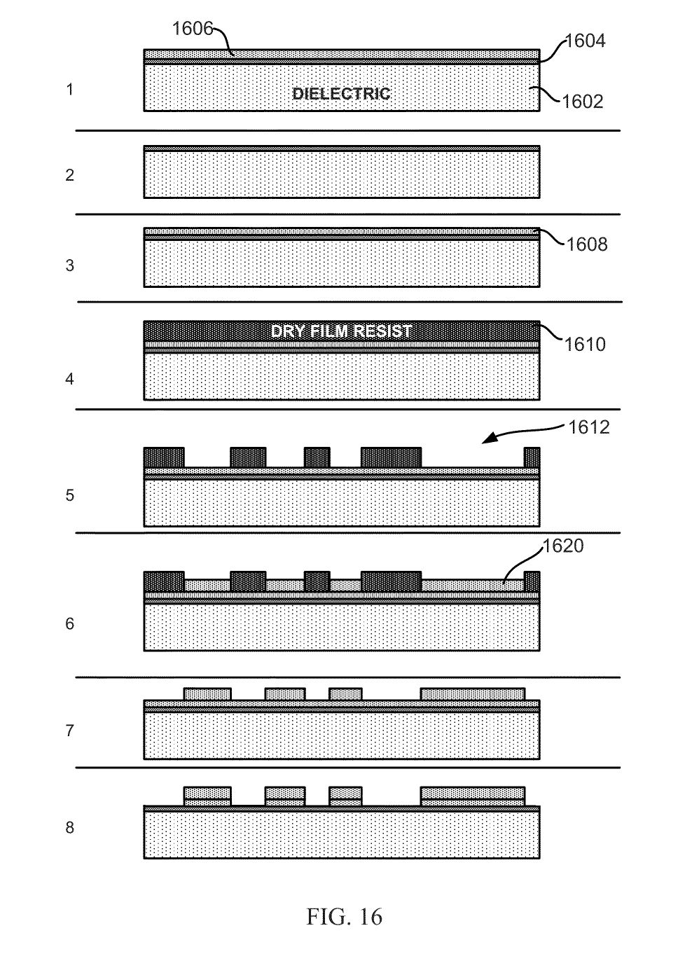

FIG. 15 illustrates a flow diagram for a semi-additive processing (SAP) patterning process for manufacturing a substrate. FIG. 15 will be described with reference to FIG. 16 which illustrates a sequence of a layer (e.g., core layer, prepreg layer) of a substrate during the SAP process of some implementations.

As shown in FIG. 15, the process 1500 may start by providing (at 1505) a dielectric layer that includes copper layer and a primer layer (e.g., a primer coated copper foil). In some implementations, the copper foil is coated with primer and then pressed on the uncured core to form the structure. The primer coated copper foil may be a copper foil. The dielectric layer may be a core layer or a prepreg layer of a substrate. As shown in stage 1 of FIG. 16, the primer 1604 is located between the copper foil 1606 and the dielectric 1602. The copper foil 1606 may be a copper composite foil in some implementations.

Next, the process drills (at 1510) the dielectric layer (e.g., core layer, prepreg layer) to create one or more openings/pattern features (e.g., via pattern features). This may be done to form one or more vias/via features that connect the front and back side of the dielectric. In some implementations, the drilling may be performed by a laser drilling operation. Moreover, in some implementations, the drilling may traverse one or more the metal layers (e.g., primer coated copper foil). In some implementations, the process may also clean the openings/pattern features (e.g., via patterns) created by the drilling operation, by, for example, de-smearing (at 1512) drilled vias/opening on the layer (e.g., core layer).

The process then etches off (at 1515) the copper foil, leaving the primer on the dielectric layer (which is shown in stage 2 of FIG. 16). Next, the process electroless plates (at 1520) a copper seed layer (e.g., copper material) on the primer in some implementations. The thickness of the copper seed layer in some implementations is about 0.1-1 microns (μm). Stage 3 of FIG. 16 illustrates a copper seed layer 1608 on the primer 1604.

Next, the process applies (at 1525) a dry film resist (DFR) and a pattern is created (at 1530) on the DFR. Stage 4 of FIG. 16 illustrates a DFR 1610 being applied on top of the copper seed layer 1608, while stage 5 of FIG. 16 illustrates the patterning of the DFR 1610. As shown in stage 5, the patterning creates openings 1612 in the DFR 1610.

After patterning (at 1530) the DFR, the process then electrolytically plates (at 1535) a copper material (e.g., copper composite material) through the pattern of the DFR. In some implementations, electrolytically plating comprises dipping the dielectric and the metal layer in a bath solution. Referring to FIG. 16, stage 6 illustrates copper (e.g., copper composite) materials 1620 being plated in the openings 1612 of the DFR 1610.

Referring back to FIG. 15, the process removes (at 1540) the DFR, selectively etches (at 1545) the copper seed layer to isolate the features (e.g., create vias, traces, pads) and ends. Referring to FIG. 16, Stage 7 illustrates the removal of the DFR 1610, while Stage 8 illustrates the defined features (e.g., composite conductive trace) after the etching process.

The above process of FIG. 15 may be repeated for each core layer or prepreg layer (dielectric layer) of the substrate.

In some implementations, the SAP process may allow for finer/smaller feature (e.g., trace, vias, pads) formation since the SAP process does not require as much etching to isolate features. However, it should be noted that the mSAP process is cheaper than the SAP process in some implementations. In some implementations, the above process may be used for produce Interstitial Via Hole (IVH) in substrates and/or Blind Via Hole (BVH) in substrates.

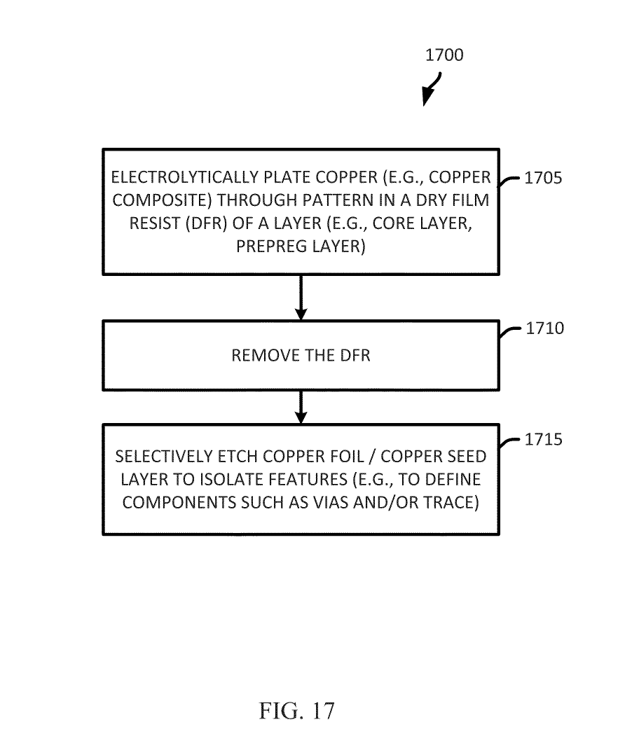

The plating processes of FIGS. 13 and 15 may be conceptually simplified to the plating process of FIG. 17 in some implementations. FIG. 17 illustrates a flow diagram for a plating method for manufacturing a substrate. As shown in FIG. 17, the method electrolytically plates (at 1705) a copper (e.g., copper composite) through a pattern in a dry film resist (DFR) on a layer of a substrate. The layer may be a dielectric layer. The layer may be a core layer or a prepreg layer of the substrate. In some implementations, the copper (e.g., copper composite) is plated over a copper seed layer, which was previously deposited on the layer (e.g., when using a SAP process). In some implementations, the copper (e.g., copper composite) is plated over a copper foil layer, which was previously on the layer (e.g., when using an mSAP process). The copper foil layer may be a copper composite material in some implementations.

Next, the method removes (at 1710) the DFR from the layer. In some implementations, removing the DFR may include chemically removing the DFR. After removing (at 1710) the DFR, the method selectively etches (at 1715) the foil or seed layer to isolate/define the features of the layer and ends. As described above, the foil may be a copper composite material.

In some implementations, a nickel alloy may be added (e.g., plated) over some or all of a copper layer (e.g., copper foil) during an mSAP process (e.g., methods of FIGS. 13, and 15). Similarly, a nickel alloy may also be added (e.g., plated) over some or all of a copper layer (e.g., copper foil) during a subtractive process.

### Exemplary Electronic Devices

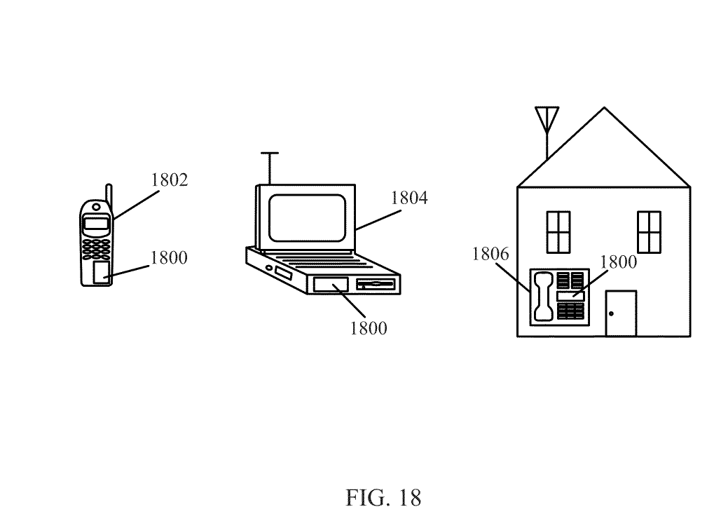

FIG. 18 illustrates various electronic devices that may be integrated with any of the aforementioned integrated devices (e.g., semiconductor device). For example, a mobile telephone 1802, a laptop computer 1804, and a fixed location terminal 1806 may include an integrated device 1800 as described herein. The integrated device 1800 may be, for example, any of the integrated devices, integrated circuits, dice or packages described herein. The devices 1802, 1804, 1806 illustrated in FIG. 18 are merely exemplary. Other electronic devices may also feature the integrated device 1800 including, but not limited to, mobile devices, hand-held personal communication systems (PCS) units, portable data units such as personal digital assistants, GPS enabled devices, navigation devices, set top boxes, music players, video players, entertainment units, fixed location data units such as meter reading equipment, communications devices, smartphones, tablet computers or any other device that stores or retrieves data or computer instructions, or any combination thereof.

While the above discussed aspects, arrangements, and embodiments are discussed with specific details and particularity, one or more of the components, steps, features and/or functions illustrated in FIGS. 1, 2, 3, 4, 5, 6, 7, 8, 9, 10, 11A-11L, 12, 13, 14, 15, 16, 17, and/or 18 may be rearranged and/or combined into a single component, step, feature or function or embodied in several components, steps, or functions. Additional elements, components, steps, and/or functions may also be added or not utilized without departing from the present disclosure.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling between two objects. For example, if object A physically touches object B, and object B touches object C, then objects A and C may still be considered coupled to one another—even if they do not directly physically touch each other.

Also, it is noted that at least some implementations have been described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

The various features associate with the examples described herein and shown in the accompanying drawings can be implemented in different examples and implementations without departing from the scope of the present disclosure. Therefore, although certain specific constructions and arrangements have been described and shown in the accompanying drawings, such embodiments are merely illustrative and not restrictive of the scope of the disclosure, since various other additions and modifications to, and deletions from, the described embodiments will be apparent to one of ordinary skill in the art. Thus, the scope of the disclosure is only determined by the literal language, and legal equivalents, of the claims which follow.

1. A substrate comprising:
a dielectric layer;
a capacitor embedded within the dielectric layer, wherein the capacitor comprises:
a first electrode disposed on a first surface;
a second electrode disposed on an opposing second surface; and
a plurality of capacitor plates positioned between the first electrode and the second electrode and extending transverse to the first and second electrodes, wherein each capacitor plate is electrically coupled to one of the first electrode or the second electrode; and
a plurality of vias extending through the dielectric, wherein at least one via is electrically coupled to the first electrode of the capacitor, and wherein at least one via is electrically coupled to the second electrode of the capacitor.

2. The substrate of claim 1, wherein the capacitor comprises a multi-layer ceramic capacitor (MLCC).

3. The substrate of claim 1, further comprising a resistive layer disposed over the first electrode and the second electrode of the capacitor.

4. The substrate of claim 1, wherein the capacitor and vias are part of a power distribution network.

5. The substrate of claim 1, wherein the capacitor is configured with a length substantially twice as long as the width.

6. The substrate of claim 1, wherein the dielectric layer comprises several dielectric layers.

7. A method of fabricating a substrate, comprising:
providing a first dielectric layer;
forming a cavity in the first dielectric layer;
providing a capacitor within the cavity of the first dielectric layer, wherein the capacitor comprises:
a first electrode disposed on a first surface;
a second electrode disposed on an opposing second surface;
wherein the first electrode and the second electrode are positioned within the cavity to be at least substantially parallel with a top and bottom surface of the dielectric layer; and
a plurality of capacitor plates positioned between the first electrode and the second electrode and extending transverse thereto, wherein each capacitor plate is electrically coupled to one of the first electrode or the second electrode;
providing a second dielectric layer to at least substantially enclose the capacitor therein; and
forming a plurality of vias through the first dielectric and the second dielectric, wherein at least one via is electrically coupled to the first electrode of the capacitor, and wherein at least one via is electrically coupled to the second electrode of the capacitor.

8. The method of claim 7, wherein providing the capacitor within the cavity of the first dielectric layer comprises:
providing a multi-layer ceramic capacitor (MLCC) within the cavity of the first dielectric layer.

9. The method of claim 7, further comprising:
providing a resistive layer over at least a portion of the first electrode and the second electrode.

10. The method of claim 9, wherein providing the resistive layer over at least a portion of the first electrode and the second electrode comprises:
screen printing the resistive layer over at least a portion of the first electrode and over at least a portion of the second electrode.

11. The method of claim 7, further comprising:
electrically coupling the vias to a power distribution network.

12. The method of claim 7, further comprising providing a third dielectric layer to at least substantially enclose the capacitor therein.

13. The method of claim 7, further comprising filling the cavity with an insert within at least a portion of the cavity.

14. An electronic device, comprising:
an integrated device including:
a substrate;
a capacitor embedded within the substrate, wherein the capacitor comprises:
a first electrode disposed on a first surface;
a second electrode disposed on an opposing second surface; and
a plurality of capacitor plates positioned between the first electrode and the second electrode and extending transverse thereto, wherein each capacitor plate is electrically coupled to one of the first electrode or the second electrode; and
a plurality of vias extending through the substrate, wherein at least one via is electrically coupled to the first electrode of the capacitor, and wherein at least one via is electrically coupled to the second electrode of the capacitor.

15. The electronic device of claim 14, wherein the first electrode and the second electrode of the capacitor each comprises a resistive layer disposed over at least a portion thereof.

16. The electronic device of claim 14, wherein the capacitor and vias are part of a power distribution network associated with the integrated device.

17. The electronic device of claim 14, wherein the capacitor is configured with a length at least substantially twice as long as the width.

18. The electronic device of claim 14, wherein the substrate comprises several dielectric layers.

19. The electronic device of claim 14, wherein the capacitor comprises a multi-layer ceramic capacitor (MLCC).

20. The electronic device of claim 14, wherein the integrated device is incorporated into at least one electronic device selected from a group of electronic devices comprising a music player, a video player, an entertainment unit, a navigation device, a communications device, a mobile device, a mobile phone, a smartphone, a personal digital assistant, a fixed location terminal, a tablet computer, and a laptop computer.
